(19) United States
(12) Patent Application Publication
(10) Pub. No.: US 2008/0198542 A1
(43) Pub. Date: Aug. 21, 2008

(54) INFORMATION PROCESSING APPARATUS

(75) Inventor: Tae-sang KIM, Suwon-si (KR)

Correspondence Address: STANZIONE & KIM, LLP, 919 18TH STREET, N.W., SUITE 440, WASHINGTON, DC, 20006, US

(73) Assignee: Samsung Electronics Co., Ltd, Suwon-si (KR)

(21) Appl. No.: 11/862,591

(22) Filed: Sep. 27, 2007

(30) Foreign Application Priority Data
Feb. 15, 2007 (KR) 2007-16219

(51) Int. Cl. H05K 7/00

(52) U.S. Cl. 361/683

(57) ABSTRACT

An information processing apparatus includes a body, a display that is coupled to the body in such a manner that the display rotates between a close position at which the display is folded on the body and an open position at which the display is unfolded against the body, a coupling part having an engaging member that projects from a plate plane of one of the body and the display and is checked so as not to project from the plate plane, and couples/decouples the display to/from the body at the close position, and a projection checking part that interlocks with the engaging member in such a manner that the engaging member does not project from the plate plane at the open position.

### CROSS-REFERENCE TO RELATED APPLICATIONS

This application claims priority from Korean Patent Application No. 10-2007-0016219, filed on Feb. 15, 2007 in the Korean Intellectual Property Office, the disclosure of which is incorporated herein in its entirety by reference.

### BACKGROUND OF THE INVENTION

1. Field of the Invention

The present general inventive concept relates to an information processing apparatus, and more particularly, to an information processing apparatus with an improved opening/closing structure.

2. Description of the Related Art

In general, an information processing apparatus processes various kinds of information which are useful for facilitation of everyday life. The information processing apparatus may include a portable computer, an MP3 player, a personal digital assistant (PDA), an electronic picture frame, a portable multimedia player, and others known in the art.

In general, the information processing apparatus has a body that processes information, and a display that is rotatably coupled to the body and forms an image. If a user finishes using the information processing apparatus, the user couples the body and the display together using a hook or the like by rotating the display with respect to the body in a coupling direction. If user wants to use the information processing apparatus, the user opens the display by rotating the display with respect to the body in a decoupling direction.

In this case, the hook or the like may project from a surface of the body or the display, which may defile an external appearance of the information processing apparatus. In addition, the projecting hook may cause damage on the hook or the information processing apparatus when the user operates the projecting hook and the information processing apparatus.

### SUMMARY OF THE INVENTION

The present general inventive concept provides an information processing apparatus with an improved usability and external appearance.

The present general inventive concept also provides an information processing apparatus which is capable of preventing the information processing apparatus from being damaged in use.

The present general inventive concept provides an information processing apparatus including a connecting part which can be installed in a body having a complicated internal structure without difficulty.

Additional aspects of the present general inventive concept will be set forth in part in the description which follows and, in part, will be obvious from the description, or may be learned by practice of the present general inventive concept.

The foregoing and/or other aspects of the present general inventive concept can be achieved by providing an information processing apparatus including a body, a display that is coupled to the body in such a manner that the display rotates between a close position at which the display is folded on the body and an open position at which the display is unfolded against the body, a coupling part including an engaging member that projects from a plate plane of one of the body and the display and is checked so as not to project from the plate plane, and couples/decouples the display to/from the body at the close position, and a projection checking part that interlocks with the engaging member in such a manner that the engaging member does not project from the plate plane at the open position.

The coupling part may further include a biting member that is provided in the other one of the body and the display and engages the engaging member.

The coupling part may further include an engaging holding member that elastically supports the engaging member to keep the display coupled to the body.

The projection checking part may include a rod that is provided to go in and out of the plate plane of one of the body and the display, and a projecting holding member that elastically supports the rod in such a manner that the rod projects from the plate plane at the open position.

The information processing apparatus may further include a wire that interconnects the engaging member and the projection checking part, and a force acting on the wire by the projecting holding member may be greater than a force acting on the wire by the engaging holding member.

The information processing apparatus may further include a connecting part that interconnects the engaging member and the projection checking part in an interlocking manner.

The connecting part may include a wire that interconnects the engaging member and the projection checking part, and a plurality of supports that support the wire and form a path of the wire.

The plurality of supports each may include a guide roller that guides the wire; and a roller pin that supports the guide roller.

The plurality of supports each may further include a wire elastic member that is coupled to at least one of the roller pin and the guide roller and elastically supports the guide roller.

The connecting part may further include an operating member that is coupled to the wire and is provided in one of the body and the display to operate the engaging member.

The body may include a portable computer body, and the display which forms an image based on information from the portable computer body.

The foregoing and/or other aspects of the present invention general inventive concept can also be achieved by providing an information processing apparatus including a body, a display movably coupled to the body in an open position and a close position with respect to the body, a coupling part comprising an engaging member to project from one of the body and the display to couple the body and the display in the close position and to decouple the body and the display in the open position, and a projection checking part to control the engaging member not to project from the one of the body and the display in the open position.

The body and the display may be in the close position according to the movement of the engaging member, and the body and the display may be in the open position when a release movement of the projection checking part between the body and the display is transferred to the coupling part.

The coupling part may be maintained in a non-projecting state in the open position according to a movement of the projection checking part occurring when the display is moved to the open position from the close position.

The coupling part and the projection checking part may be spaced-apart from each other by a distance within the one of the body and the display.

The coupling part may be disposed at a first position and the projection checking part is disposed at a second position spaced-apart from each other.

The display may be movable between the open position and the close position about an axis, the coupling part may be disposed at a first position, and the projection checking part may be disposed at a second position closer to the axis than the first position.

The body may include a keyboard, and the coupling part and the projection checking part are disposed at first and second sides of the keyboard, respectively.

The foregoing and/or other aspects of the present invention general inventive concept can also be achieved by providing an information processing apparatus including a body, a display movably coupled to the body in an open position and a close position with respect to the body, and a coupling part comprising an engaging member movably disposed on one of the body and the display to project from the one of the body and the display and couple the display to the body in the close position, and not to project from the one of the body and the display in the open position.

### BRIEF DESCRIPTION OF THE DRAWINGS

The above and/or other aspects of the present general inventive concept will become apparent and more readily appreciated from the following description of the exemplary embodiments, taken in conjunction with the accompanying drawings, in which:

FIG. 1 is a perspective view illustrating a portable computer according to an exemplary embodiment of the present general inventive concept;

FIG. 2 is a partially-cut perspective view of the portable computer of FIG. 1;

FIGS. 3A and 3B are a side sectional view and a front sectional view illustrating a coupling part and a connecting part of the portable computer of FIG. 1, respectively;

FIG. 4 is a side sectional view of FIG. 1;

FIGS. 5A to 5C are a sectional view and a partially-cut view illustrating movement of a display of FIG. 1 from a close position to an open position; and

FIGS. 6A to 6C are a sectional view and a partially-cut view illustrating movement of a display of FIG. 1 from an open position to a close position.

### DETAILED DESCRIPTION OF THE PREFERRED EMBODIMENTS

Reference will now be made in detail to the embodiments of the present general inventive concept, examples of which are illustrated in the accompanying drawings, wherein like reference numerals refer to like elements throughout. The embodiments are described below so as to explain the present general inventive concept by referring to the figures.

An information processing apparatus may include a portable computer, a personal digital assistant, an electronic scheduler and others known in the art, but in the following description, the portable computer will be illustrated as an exemplary embodiment of the present invention. Also, in the following description, the portable computer is divided into a body and a display for convenience of description without being limited to this.

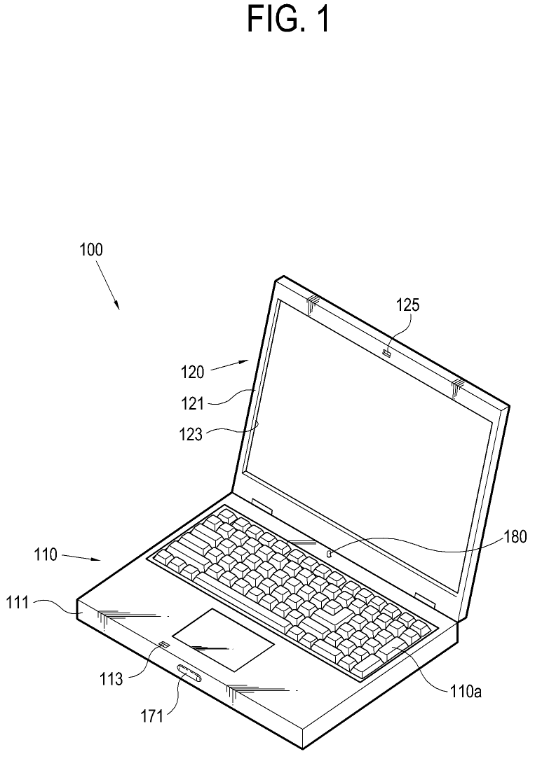

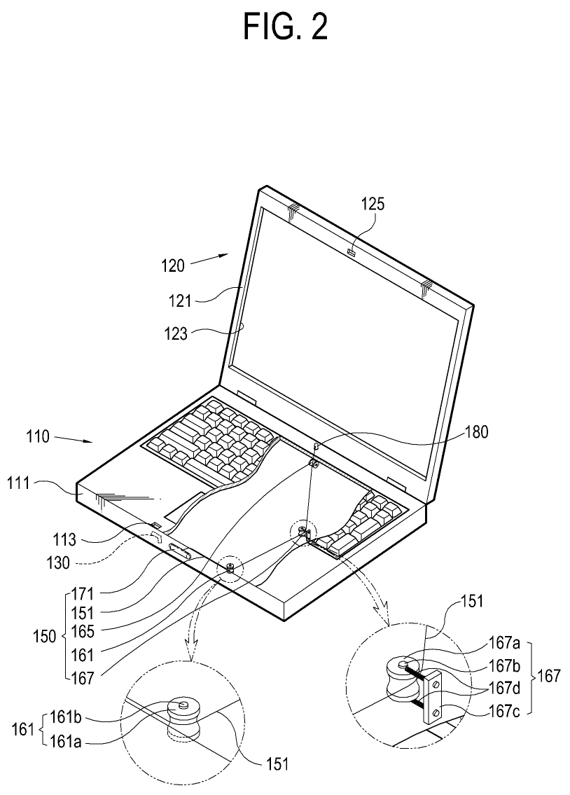

In the exemplary embodiment, an information processing apparatus 100 includes a body 110, a display 120, and a projection checking part (or projection controlling part) 180, as illustrated in FIG. 1. The information processing apparatus 100 further includes a coupling part 130 and a coupling part 150 as illustrated in FIG. 2.

The body 110 has a casing 111 that forms an external appearance. The body 110 includes a keyboard 110a that allows a user to input information such as characters, and various connectors (not shown) that can be electrically connected to an outside thereof. The body 110 may further include various storage medium connectors (not illustrated) through which various kinds of information can be inputted from the outside to a storage medium.

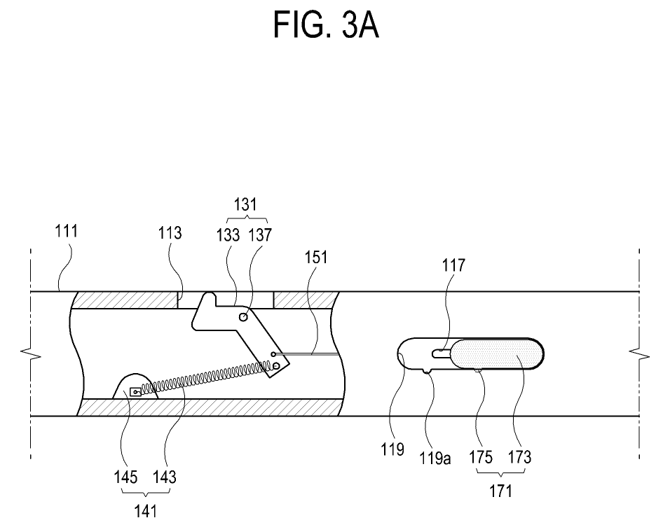

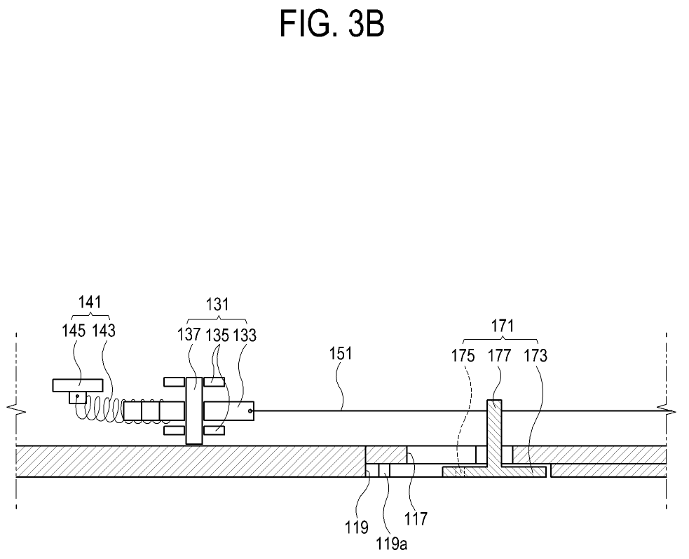

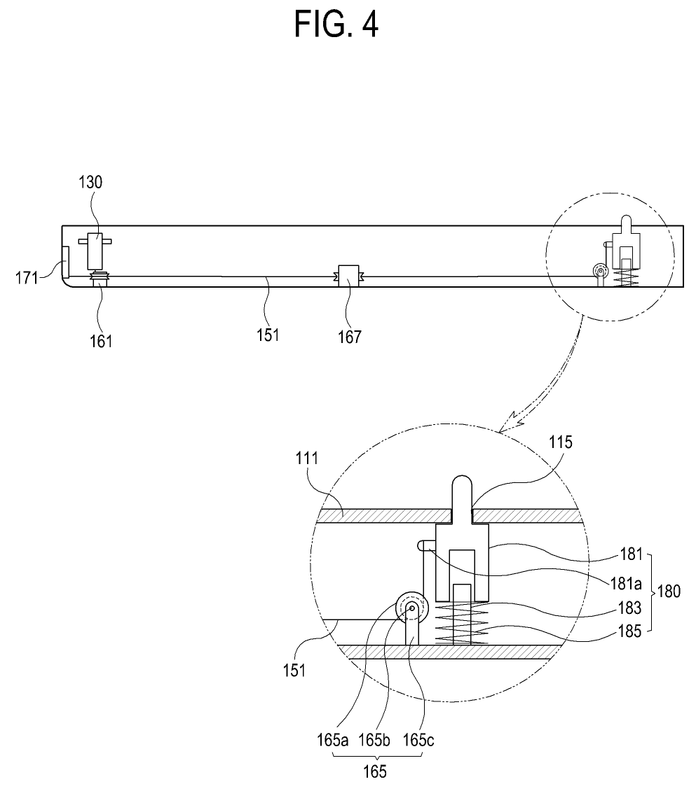

Referring to FIGS. 1, 2, 3, and 4, the body 110 includes an engaging member receiving hole 113 formed in a front side of a plate plane thereof, a rod receiving hole 115 (see FIG. 4) formed in the rear of the plate plane to receive a portion of the projection checking part 180, a locking bar receiving slot 117 (see FIGS. 3A and 3B) formed in the front side of the plate plane, and an operating plate receiving part 119 (see FIGS. 3A and 3B) depressed or recessed from the front side of the plate plane. A plurality of operating projection grooves 119a are formed in a lower side of the operating plate receiving part 119.

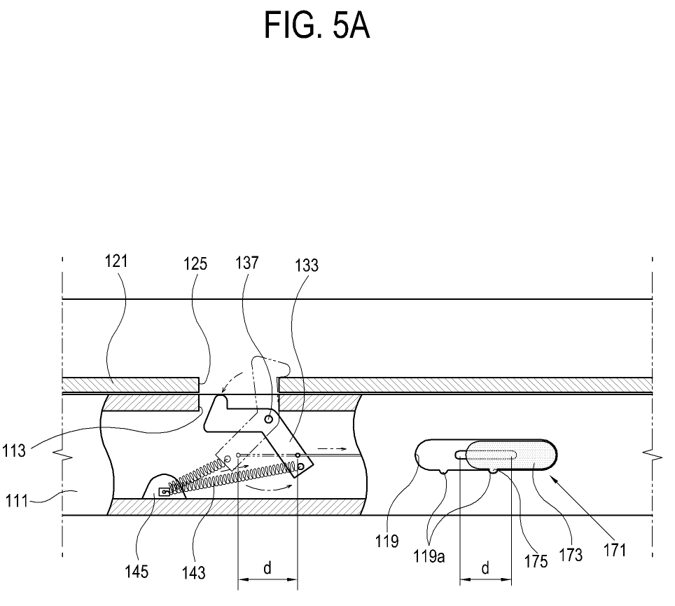

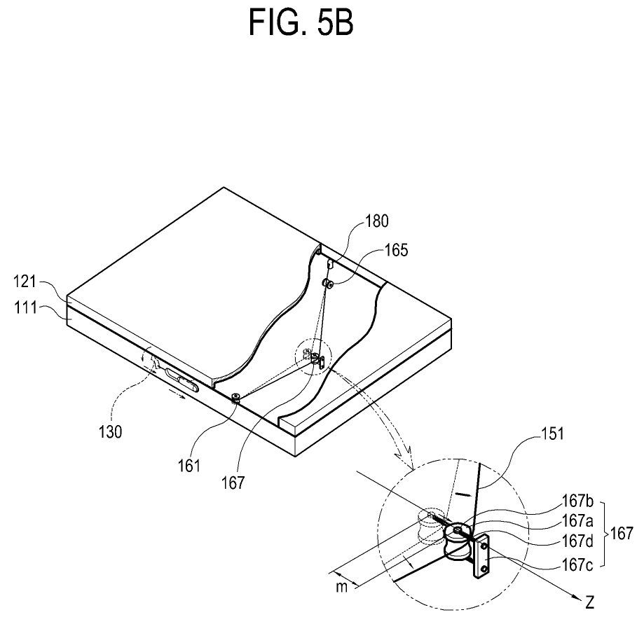

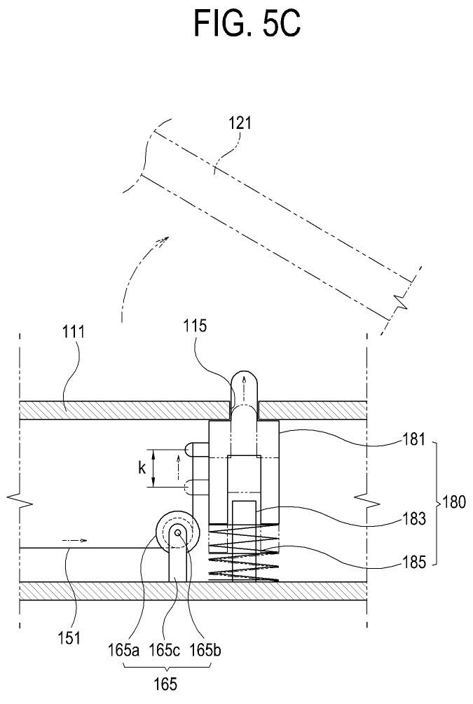

The display 120 is coupled to the body 110 and rotates between a close position (see FIG. 5B) at which the display 120 is folded on the body 110 and an open position (see FIGS. 1 and 2) at which the display 120 is unfolded from the body 110. The display 120 includes a cover 121 that forms an external appearance. The display 120 may be provided with an antenna (not shown) through which various kinds of information are received and transmitted, and a picture display part 123 which can display an image formed in a liquid crystal panel according to the information or internal data.

The display 120 includes a biting member 125 which passes through a plate plane thereof or is depressed from the plate plane and engages an engaging hook 133 (FIG. 5A) to couple the body 110 and the display 120.

The coupling part 130 is checked (or controlled) so as not to project from the plate plane of the body 110 and couples/decouples the display 120 and the body 110 at/from the close position. As illustrated in FIGS. 3A and 3B, the coupling part 130 includes an engaging member 131, and an engaging holding member 141, and further includes the biting member 125 that engages with the engaging member 131.

In an embodiment of the present general inventive concept, the coupling part 130 may be provided or controlled to project from the plate plane of the display 120 or to be checked (or controlled) so as not to project from the plate plane of the display 120. In other words, the engaging member 131 and the engaging holding member 141 may be provided in the display 120 and the biting member 125 may be provided in the body 110. In an embodiment, instead of the engaging hook 133 and the biting member 125, the coupling part 130 may employ conventional members when the conventional members are used to move a projecting position and a non-projecting position from the plate plane of the display 120.

Referring to FIGS. 3A and 3B, the engaging member 131 is coupled to the body 110 and projects from the plate plane of the body 110 or to be checked or controlled so as not to project from the plate plane of the body 110. The engaging member 131 engages the biting member 125 provided in the display 120 so that the body 110 can be coupled/decoupled to/from the display 120. The engaging member 131 includes the engaging hook 133, a hook bracket 135 and an engaging hook pin 137.

The engaging hook 133 has a plate-like hook shape which is formed in an upper portion of the engaging hook 133 and engages the biting member 125 to move to a coupling position and a decoupling position, to thereby couple/decouple the body 110 to/from the display 120. A distal end of the engaging hook 133 may hold the biting member 125 to couple the display 120 to the plate plane of the body 110 in the coupling position and move away from the biting member 125 to decouple the display 120 from the plate plane of the body 110 in the decoupling position. The engaging hook pin 137 is coupled to a central portion of the engaging hook 133 so that the engaging hook 133 can rotate. An engaging holding spring 143 is coupled to a bottom left side of the engaging hook 133 and a wire 151 is coupled to a bottom right side of the engaging hook 133. Thus, the engaging hook 133 can be rotated about the engaging hook pin 137.

The hook bracket 135 is provided on a bottom plate of the casing 111 at both sides of the engaging hook 133 to support the engaging hook pin 137 and is coupled to the body 110. The hook bracket 135 may be provided in various ways if only it can support the engaging hook pin 137.

The engaging hook pin 137 is coupled to the engaging hook 133 so that the engaging hook 133 can be rotated, and is coupled to and supported by the hook bracket 135.

The engaging holding member 141 supports the engaging hook 133 elastically so that the engaging hook 133 can keep coupled to the biting member 125. The engaging holding member 141 includes the engaging holding elastic member 143 which can simply support the engaging hook 133 elastically, and an engaging holding bracket 145.

The engaging holding elastic member 143 may include a spring but may include one selected from conventional elastic members. The engaging holding elastic member 143 has one end coupled to a lower portion of the engaging hook 133 and the other end coupled to the engaging holding bracket 145.

Thus, the coupling between the body 110 and the display 120 can be more stably held when the engaging holding member 141 biases the engaging pin 137 toward the coupling position. That is, a coupling state of the body 110 and the display 120 can be stably maintained by a biasing force of the engaging holding member 141.

The engaging holding bracket 145 is coupled to the body 110 to support the engaging holding elastic member 143.

The engaging member 131 passes through the engaging member receiving hole 114 of the casing 111 and passes through an opening of the cover 121 of the display 120 to be coupled to the biting member 125. For example, the biting member 125 may be a member having a bent or depressed shape of the cover 121 and may engage the engaging member 131. The biting member 125 is provided in the display 120 and has an advantage to secure or provide a space for various functions and components (for example, a high speed downlink packet access (HSDPA), a digital multimedia broadcasting (DMB), a wireless LAN, etc.) to be installed in the display 120. In an embodiment, the biting member 125 may be provided in the body 110.

Thus, competitiveness of products can be improved since the space for various functions and components can be secured in at least one of the body 110 and the display 120 of the information processing apparatus.

A connecting part 150 interconnects the engaging member 131 and the projection checking part 180. The connecting part 150 includes the wire 151 and supports 161, 165 and 167.

As an alternative embodiment, the connecting part 150 may be also provided in either the body 110 or the display 120. That is, if the projection checking part 180 is provided in the display 120, the connecting part 150 may be provided in the display 120 or the body 110 if necessary.

The wire 151 interconnects the engaging member 131 and the projection checking part 180 to be engaged. It is possible that the wire 151 is made of a deformable material having no elasticity. The wire 151 may include such material as a piano wire. As illustrated in FIGS. 2 and 4, the wire 151 contacts guide rollers 161a, 165a and 167a and can always remain in a tensed condition by a force acting between the engaging member 131 and the projection checking part 180. A left end portion of the wire 151 is coupled to the engaging member 131 as illustrated in FIGS. 3A and 3B, and a right end portion of the wire 151 is coupled to a rod holder 181a of the projection checking part 180 as illustrated in FIG. 4. In addition, the wire 151 is coupled to an operating locking bar 177 of an operating member 171 between the engaging member 131 and a front support 161 as illustrated in FIG. 3B.

The plurality of supports 161, 165 and 167 support the wire 151 and change a path of the wire 151. The supports 161, 165 and 167 include the front support 161, a rear support 165 and a middle support 167 which are disposed between upper and bottom plates of the casing 111.

As an alternative embodiment, the supports 161, 165 and 167 may have various paths depending on arrangement of parts within the body 110 and the number of supports 161, 165 and 167 may be two, four, five, etc.

The front support 161 is provided between the operating member 171 and the middle support 167 to form the path of the wire 151 and supports the wire 151. The front support 161 includes a front guide roller 161a that contacts and guides the wire 151, and a front roller pin 161b that rotatably supports the front guide roller 161a. The front roller pin 161b is coupled to the body 110. Thus, the wire 151 contacts the front guide roller 161a and moves between the engaging member 131 and the projection checking part 180 without difficulty.

The middle support 167 is provided between the front support 161 and the rear support 165 to support the wire 151 and forms the path of the wire 151. The middle support 167 includes a middle guide roller 167a that contacts and guides the wire 151, and a middle roller pin 167b that rotatably supports the middle guide roller 167a. The middle support 167 further includes a wire elastic member 167d that is coupled to the middle roller pin 167b and a middle bracket 167c to provide a predetermined tensile force (or tension) to the wire 151 to elastically support the middle guide roller 167a. The middle support 167 further includes a middle bracket 167c that is coupled to the body 110 and supports the wire elastic member 167d. Although the middle support 167 is provided singly in this embodiment, it may be provided in plural if necessary.

Thus, if the engaging member 131 is decoupled from the biting member 125 by operating the operating member 171 before the display 120 is opened, since the middle support 167 can give the predetermined tensile force to the wire 151, the path of the wire 151 can be stably maintained and the wire 151 can always remain in a tensed condition. Since the wire 151 is in the tensed condition, the engaging member 131, the operating member 171, and the projecting checking part 180 can move to and maintain in one of the coupling position and the decoupling position

The rear support 165 is provided between the middle support 167 and the projection checking part 180 to support the wire 151 so as to form the path of the wire 151. The rear support 165 includes a rear guide roller 165a that contacts and guides the wire 151, and a rear roller pin 165b that rotatably supports the rear guide roller 165a. The rear roller pin 165b is supported by a rear roller bracket 165c coupled to the body 110. Thus, the wire 151 can contact the rear guide roller 165a and move between the engaging member 131 and the projection checking part 180 without difficulty.

Thus, since the supports 161, 165 and 167 having the wire 151 can be arranged in various ways within an internal complicated structure of the body 110, adaptability can be improved with relaxed restrictions on design.

The operating member 171 is coupled to the wire 151 and is also coupled to the body 110 so that a user can operate the operating member 171. The operating member 171 includes an operating plate 173, an operating projection 175 and the operating locking bar 177. The operating member 171 decouples the engaging hook 133 from the biting member 125 before the display 120 is opened from the body 110.

The operating plate 173 is disposed in the operating plate receiving part 119 depressed or recessed in the front side of the body 110 and has a board shape. The operating plate 173 is provided with the operating locking bar 177 which is projected inside to a plate plane and is coupled to the wire 151. The operating plate 173 has the operating projection 175 which projects from a side thereof to engage the operating projection groove 119a of the operating plate receiving part 119 to hold the operating plate 173 at the close and open positions. The operating plate 173 may be disposed to slidably move in the operating plate receiving part 119 to allow the operating projection 175 and the operating projection groove 119a to be coupled to each other and to be decoupled from each other according to the close and open positions.

Thus, a user can simply decouple the engaging member 131 from the biting member 125 by moving the wire 151 by operating the operating plate 173 which is exposed to an outside of the body 111.

If the display 120 is at the open position, the projection checking part 180 causes the engaging hook 133 of the engaging member 131 not to project from the plate plane of the casing 111 of the body 110. That is, the projection checking part 180 hides the engaging hook 133 of the engaging member 131 beneath the plate plane of the casing 111 of the body 110. The projection checking part 180 is disposed in a rear central portion of the casing 111 of the body 110. The projection checking part 180 includes a rod 181, a rod guide 183 and a projecting holding member 185.

According to the present general inventive concept, the projecting checking part 180 may be provided in the display 120. The projecting checking part 180 may be provided at various positions at which the projecting checking part 180 can go in and out of the plate plane of the casing 111 by the rotation of the display 120, if necessary, as well as the rear central portion of the casing 111 of the body.

The rod 181 has a cylindrical shape and is movably coupled to the casing 111 so that the rod 181 can pass through the rod receiving hole 115 formed in the plate plane of the casing 111 of the body 110. Specifically, the rod 181 has an upper cylindrical portion which is slidably coupled to the rod receiving hole 115 and a lower cylindrical portion which is larger than the upper cylindrical portion and limits a height of the rod 181 projecting from the plate plane of the casing 111. A central portion of the lower cylindrical portion of the rod 181 is formed with a space into which the rod guide 183 is received to guide a vertical movement of the rod 181.

The rod 181 is provided with the rod holder 181a that projects from a circumference of the lower cylindrical portion and is coupled to the wire 151 to support the wire 151.

The rod guide 183 is coupled to the body 110 to be inserted into the central portion of the rod 181 and to slidably guide the rod 181 while the rod 181 vertically moves to project from the plate plane of the casing 111 or retreat into the plate plane of the casing 111. The rod guide 183 has preferably a cylindrical shape but may have a polygonal tube. The rod guide 183 may have a shape corresponding to a shape of the rod 181

The projecting holding member 185 is coupled between the rod 181 and the casing 111 of the body 110 and elastically presses the rod 181 so that the rod 181 projects from the plate plane of the casing 111 of the body 110. The projecting holding member 185 is preferably constituted by a spring as in this exemplary embodiment, but may employ any conventional elastic member if it elastically presses the rod 181.

According to the present general inventive concept, it is possible that the tensile force acting on the wire 151 by the projecting holding member 185 is greater than the tensile force acting on the wire 151 by the engaging holding member 141.

Thus, since the engaging member 131 does not project from the plate plane of the casing 111 by the projecting checking part 180, the information processing apparatus looks fine externally. In addition, since a user is not caught with the engaging member 131, the user can use the information processing apparatus safely and conveniently. Here, the plate plane of the casing 111 may a plane on which an input unit, e.g., a keyboard or mouse, is disposed, or may be a plane to face the display 120 when the body 110 and the display 120 are in a closing position or a coupling position.

Thus, the present general inventive concept provides a simple structure in which the engaging member does not project.

Hereinafter, an operation of the information processing apparatus 100 as constructed above according to the exemplary embodiment will be described with reference to FIGS. 5A to 5C.

FIGS. 5A to 5C are a sectional view and a partially-cut view illustrating a relative movement of the display 120 with respect to the body 110 of FIG. 1 in a process in which the display 120 moves from the close position to the open position.

As illustrated in FIG. 5A, a user presses the operating plate 173 from left to right so that the operating projection 175 engages one of two operating projection grooves 119a to decouple the body and the display and place the body and the display in the open position. In the close position, the operating projection 175 engages the other one of the two operating projection grooves 119a. As the operating plate 173 moves from left to right, the wire 151 moves by a distance ‘d’ in a arrow direction as indicated in FIG. 5A. That is, the wire 151 coupled to the operating locking bar 177 moves according to the movement of the operating plate 173.

At the same time, a lower end portion of the engaging hook 133 coupled to a left end portion of the wire 151 rotates counterclockwise about the engaging hook pin 137 from left to right. Thus, the engaging hook 133 rotates to be decoupled from the biting member 125. During this decoupling process, the engaging holding elastic member 143 is elongated, and the wire 151 between the operating member 171 and the rear support 165 remains elongated by a distance ‘d.’

Next, a supporting state of the elongated wire 151 between the operating member 171 and the rear support 165 will be described with reference to FIG. 5B. The elongated wire 151 maintains a tensed condition by a force of the wire elastic member 167d coupled to the middle roller pin 167b to pull or bias the middle guide roller 167a toward the middle bracket 167c. A rotation axial line of the middle roller pin 167b of the middle support 167 moves by a distance ‘m’ from a position indicated by a dotted line to a position indicated by a solid line along a ‘Z’ direction.

Thus, since the path of the wire 151 further increases between the operating member 171 and the rear support 165, the length of the wire 151 is lengthened by the operation of the operating member 171 to compensate for the increased path. Since the compensation of the length of the wire 151 is made at the same time of movement of the operating member 171, the wire 151 can always remain in the tensed state.

Next, the user rotates the display 120 with respect to the body 110 in a decoupled state with the engaging member 131, as illustrated in FIG. 5C. Thus, the cover 121 of the display 120 which presses the rod 181 of the projecting checking part 180 is separated from the plate plane of the casing 111, and then the rod 181 is biased to project from the plate plane of the casing 111 by a pressure applied from the projecting holding member 185 that elastically presses the rod 181.

The rod holder 181a moves upward with the movement of the rod 181, and accordingly, the wire 151 supported on the rod holder 181a moves upward. In this case, a movement distance (‘k’ in FIG. 5C) of the wire 151 may be different from the distance ‘d’ of the wire 151 illustrated in FIG. 5A. That is, a difference between the distance ‘d’ in FIG. 5A and the distance ‘k’ in FIG. 5C can be compensated by movement of the wire elastic member 167d of the middle support 167.

Thus, the wire 151 supported on the rod holder 181a can pull the engaging hook 133 through the rear support 165, the middle support 167, the front support 161 and the operating member 171 so that the engaging hook 133 does not project from the plate plane of the casing 111.

In this case, a force acting or exerted on the wire 151 may be properly adjusted to achieve the above operation smoothly. Specifically, the elastic force of the engaging holding elastic member 143, a coupling force between the operating projection 175 and the operating projection groove 119a, an elastic force of the wire elastic member 167d of the middle support 167, and an elastic force of the projecting holding member 185 may be properly adjusted. For example, a force acting on the wire 151 at the open position by the projecting holding member 185 is larger than the sum of a force acting on the wire 151 by the engaging holding elastic member 143 and a force acting on the wire 151 by the wire elastic member 167d.

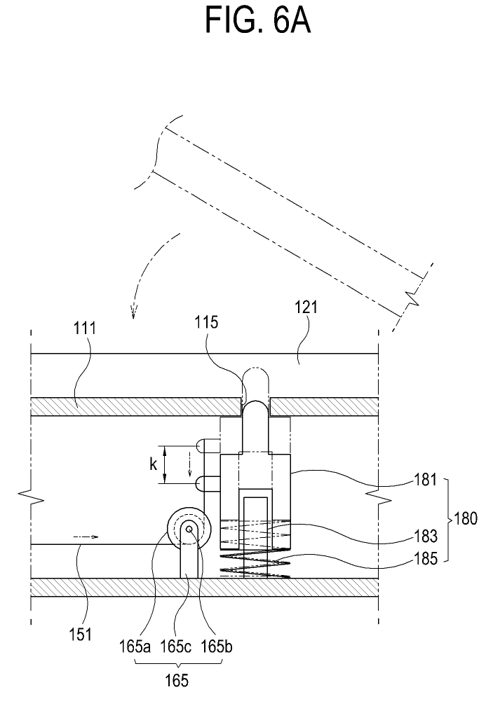

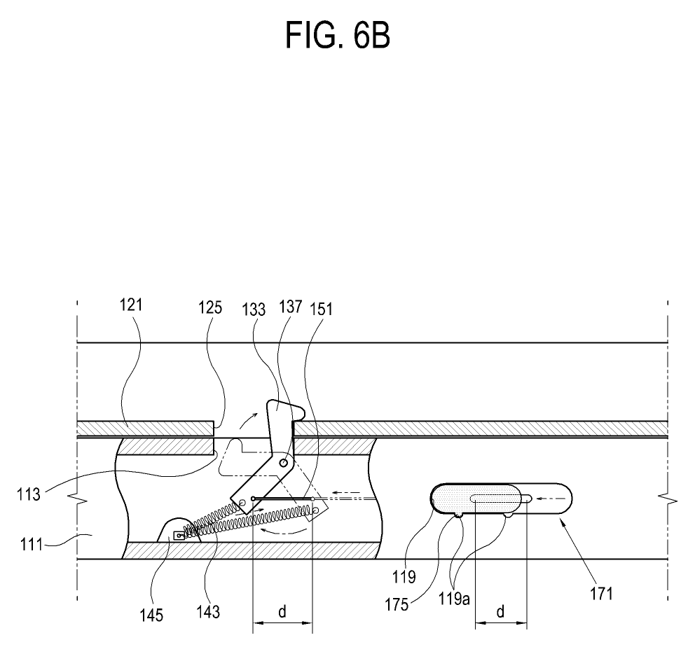

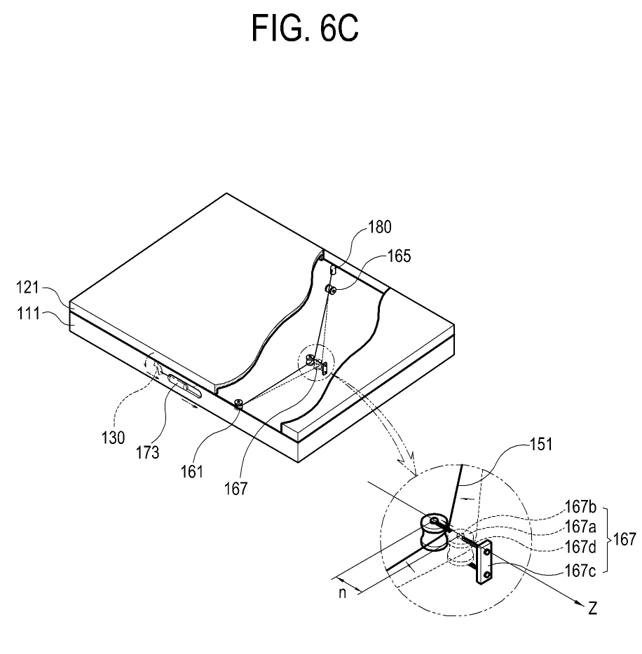

Next, a process in which the display 120 moves from the open position to the close position will be described with reference to FIGS. 6A to 6C.

First, as illustrated in FIG. 6A, if a user presses and rotates the display 120 with respect to the body 110, the rod 181 is pressed while the plate plane of the casing 111 approaches to the plate plane of the cover 121. The rod 181 moves downward by the distance ‘k’. Accordingly, the rod 181 does not project from the plate plane of the casing 111 and the force acting (or exerted) on the wire 151 by the projecting holding member 185 is vanished (or removed).

Since there is no force acting on the wire 151 by the projecting holding member 185, the engaging holding elastic member 143 is restored as shown in FIG. 6B. Thus, the engaging hook 133 rotates clockwise about the engaging hook pin 137. Thus, an upper hook portion of the engaging hook 133 engages with the biting member 125, and the wire 151 coupled to a lower portion of the engaging hook 133 moves by the distance ‘d’ from the rear support 165 toward the engaging hook 133. At the same time, the operating member 171 also moves by the distance ‘d’ to the left side and the operating projection 175 engages with the operating projection groove 119a to check movement of the operating plate 173.

In addition, as shown in FIG. 6C, a difference between the movement distances ‘d’ and ‘k’ of the wire 151 may be compensated as follows. Since the elastic force of the engaging holding elastic member 143 which pulls the wire 151 is greater than the elastic force of the wire elastic member 167d, the middle guide roller 167a moves away from the middle bracket 167c. At the same time, the wire elastic member 167d is elongated. That is, the rotation axial line of the middle roller pin 167b of the middle support 167 moves by a distance ‘n’ from a position indicated by a dotted line to a position indicated by a solid line along a ‘Z’ direction.

Thus, since the path of the wire 151 further decreases between the operating member 171 and the rear support 165, the length of the wire 151 can be compensated. Since the compensation of the length of the wire 151 is made at the same time with a movement of the rod 181, the wire 151 can always remain in the tensed state or condition.

Thus, the display 120 can be simply coupled to the body 110 at the close position.

As apparent from the above description, the present general inventive concept provides an information processing apparatus with improved usability and external appearance.

In addition, the present general inventive concept provides an information processing apparatus which is capable of preventing the engaging member from being damaged and improving the safety of a user.

Furthermore, the present general inventive concept provides an information processing apparatus with improved space availability and product competitiveness, which includes the connecting part that can be installed in the body having a complicated internal structure without difficulty.

Although a few embodiments of the present general inventive concept have been shown and described, it will be appreciated by those skilled in the art that changes may be made in these embodiments without departing from the principles and spirit of the general inventive concept, the scope of which is defined in the appended claims and their equivalents.

What is claimed is:

1. An information processing apparatus comprising:
a body;
a display that is coupled to the body in such a manner that the display rotates between a close position at which the display is folded on the body and an open position at which the display is unfolded against the body;
a coupling part comprising an engaging member that projects from a plate plane of one of the body and the display to couple the display to the body in the close position, and couples and decouples the display and the body in the close position and the open position; and
a projection checking part that interlocks with the engaging member to control the engaging member not to project from the plate plane at the open position.

2. The information processing apparatus according to claim 1, wherein the coupling part further comprises a biting member that is provided in the other one of the body and the display to be engaged with the engaging member.

3. The information processing apparatus according to claim 2, wherein the coupling part further comprises an engaging holding member that elastically supports the engaging member to maintain the display and the body in the close position.

4. The information processing apparatus according to claim 3, wherein the projection checking part comprises:
a rod that is provided to project from and retreat from the plate plane of one of the body and the display; and
a projecting holding member that elastically supports the rod in such a manner that the rod projects from the plate plane at the open position.

5. The information processing apparatus according to claim 4, further comprising a wire that interconnects the engaging member and the projection checking part,
wherein a force acting on the wire by the projecting holding member is larger than a force acting on the wire by the engaging holding member.

6. The information processing apparatus according to claim 3, further comprising:
a connecting part that interconnects the engaging member and the projection checking part in an interlocking manner.

7. The information processing apparatus according to claim 6, wherein the connecting part comprises:
a wire that interconnects the engaging member and the projection checking part; and
a plurality of supports that support the wire and form a path of the wire.

8. The information processing apparatus according to claim 7, wherein the plurality of supports each comprises:
a guide roller that guides the wire; and
a roller pin that supports the guide roller.

9. The information processing apparatus according to claim 8, wherein the plurality of supports each further comprises a wire elastic member that is coupled to at least one of the roller pin and the guide roller and elastically supports the guide roller.

10. The information processing apparatus according to claim 7, wherein the connecting part further comprises an operating member that is coupled to the wire and is provided in one of the body and the display to operate the engaging member.

11. The information processing apparatus according to claim 1, wherein the coupling part further comprises an engaging holding member that elastically supports the engaging member to maintain the display and the body in the close position.

12. The information processing apparatus according to claim 11, wherein the projection checking part comprises:
a rod that is provided to project from and retreat from the plate plane of one of the body and the display; and
a projecting holding member that elastically supports the rod in such a manner that the rod projects from the plate plane at the open position.

13. The information processing apparatus according to claim 12, further comprising:
a wire that interconnects the engaging member and the projection checking part,
wherein a force acting on the wire by the projecting holding member is larger than a force acting on the wire by the engaging holding member.

14. The information processing apparatus according to claim 11, further comprising:
a connecting part that interconnects the engaging member and the projection checking part in an interlocking manner.

15. The information processing apparatus according to claim 14, wherein the connecting part comprises:
a wire that interconnects the engaging member and the projection checking part; and
a plurality of supports that support the wire and form a path of the wire.

16. The information processing apparatus according to claim 15, wherein the plurality of supports each comprises:
a guide roller that guides the wire; and
a roller pin that supports the guide roller.

17. The information processing apparatus according to claim 16, wherein the plurality of supports each further comprises a wire elastic member that is coupled to at least one of the roller pin and the guide roller and elastically supports the guide roller.

18. The information processing apparatus according to claim 15, wherein the connecting part further comprises an operating member that is coupled to the wire and is provided in one of the body and the display to operate the engaging member.

19. The information processing apparatus according to claim 1, wherein the body comprises a portable computer body to process information, and the display forms an image based on the information from the portable computer body.

20. An information processing apparatus comprising:
a body;
a display movably coupled to the body in an open position and a close position with respect to the body;
a coupling part comprising an engaging member to project from one of the body and the display to couple the body and the display in the close position and to decouple the body and the display in the open position; and
a projection checking part to control the engaging member not to project from the one of the body and the display in the open position.

21. The information processing apparatus of claim 20, wherein the body and the display are in the close position according to the movement of the engaging member, and the body and the display are in the open position when a release movement of the projection checking part between the body and the display is transferred to the coupling part.

22. The information processing apparatus of claim 20, wherein the coupling part is maintained in a non-projecting state in the open position according to a movement of the projection checking part occurring when the display is moved to the open position from the close position.

23. The information processing apparatus of claim 20, wherein the coupling part and the projection checking part are spaced-apart from each other by a distance within the one of the body and the display.

24. The information processing apparatus of claim 20, wherein the coupling part is disposed at a first position and the projection checking part is disposed at a second position spaced-apart from each other.

25. The information processing apparatus of claim 20, wherein:
the display is movable between the open position and the close position about an axis;
the coupling part is disposed at a first position; and
the projection checking part is disposed at a second position closer to the axis than the first position.

26. The information processing apparatus of claim 20, wherein the body comprises a keyboard, and the coupling part and the projection checking part are disposed at first and second sides of the keyboard, respectively.
